(19) United States
(12) Patent Application Publication
(10) Pub. No.: US 2024/0199071 A1
(43) Pub. Date: Jun. 20, 2024

(54) GENERATING A DRIVING ASSISTANT MODEL USING SYNTHETIC DATA GENERATED USING HISTORICAL SHADOW DRIVER FAILURES AND GENERATIVE RENDERING WITH PHYSICAL CONSTRAINTS

(71) Applicant: Cognata Ltd., Rehovot (IL)

(72) Inventor: Dan ATSMON, Rehovot (IL)

(73) Assignee: Cognata Ltd., Rehovot (IL)

(21) Appl. No.: 18/542,857

(22) Filed: Dec. 18, 2023

Related U.S. Application Data
(60) Provisional application No. 63/433,465, filed on Dec. 18, 2022.

(51) Int. Cl. B60W 60/00; B60W 50/06; G06F 30/27

(52) U.S. Cl. CPC B60W 60/001; B60W 50/06; G06F 30/27; B60W 2050/0019; B60W 2556/00

(57) ABSTRACT

A method for generating a driving assistant model, comprising: computing at least one semantic driving scenario by computing at least one permutation of at least one initial semantic driving scenario; providing the at least one semantic driving scenario to a simulation generator to produce simulated driving data describing at least one simulated driving environment; training a driving assistant model using the simulated driving data to produce a trained driving assistant model; and providing by the trained driving assistant model at least one driving instruction to at least one autonomous driving model while the at least one autonomous driving model is operating.

### RELATED APPLICATION

This application claims the benefit of priority of U.S. Provisional Patent Application No. 63/433,465 filed on Dec. 18, 2022, the contents of which are incorporated herein by reference in their entirety.

### FIELD AND BACKGROUND OF THE INVENTION

Some embodiments described in the present disclosure relate to simulated data and, more specifically, but not exclusively, to simulated data for autonomous driving systems. In addition, some embodiments described herewithin relate to a model for assisting autonomous operation and, more specifically, but not exclusively, for assisting an autonomous driving model.

The term “autonomous driving system” (ADS) refers to a vehicle that is capable of sensing its environment and moving safely with some human input. The term “advanced driver-assistance system” (ADAS) refers to a system that aids a vehicle driver while driving by sensing its environment. A vehicle comprising an ADAS may comprise one or more sensors, each capturing a signal providing input to the ADAS.

Some examples of a sensor are an image sensor, such as a camera, a video camera, a rolling shutter camera, an electromagnetic radiation sensor, an acceleration sensor, a velocity sensor, an audio sensor, for example a microphone, a radio detection and ranging sensor (radar), a laser imaging, detection, a ranging sensor (LIDAR), an ultrasonic sensor, a thermal sensor, and a far infra-red (FIR) sensor. A camera may capture visible light frequencies. A camera may capture invisible light frequencies such as infra-red light frequencies and ultra-violet light frequencies.

For brevity, the following description focuses on training a model for an ADS and additionally or alternatively for assisting an ADS, however the methods and systems described below may be applied to other autonomous systems, for example an ADAS. In addition, the methods and systems described below may be used additionally or alternatively for testing an autonomous system, additionally or alternatively validating an autonomous system, and additionally or alternatively verifying an autonomous system.

As used herein, the term driving scenario refers to data describing a driving environment and one or more actors, acting in the driving environment. The driving environment may comprise a map describing a topology of a terrain, and one or more static objects of the driving environment, some examples being a paved road, a road mark, a sidewalk, a parked vehicle, a tree, a traffic sign, and a building. An actor is a moving object of the driving environment, for example a vehicle or a pedestrian. Another example is an animal. An actor may be acting in the air of the driving environment, for example a bird or a rock thrown by another actor of the driving environment. Another example is an object falling off of another object, for example an object falling off a building or an object falling off a moving vehicle.

In the field of autonomous driving, it is common practice for a system, for example an ADS or ADAS, to include one or more machine learning models, henceforth referred to as autonomous driving models. Such machine learning models may serve as a system's corner-stone for learning how to function well on the road. It is common practice to use driving scenarios for training such machine learning models. Other uses of driving scenarios in the field of autonomous driving include validation of an autonomous driving model, verification of an autonomous driving model, and testing of an autonomous driving model. Driving scenarios may also be used for one or more of testing, validating, verifying, and training of a system, such as an ADS or an ADAS.

For brevity, as used herewithin the term ADS is used to mean a system comprising one or more autonomous driving models.

In the field of autonomous driving, the term “shadow driving” refers to an ADS operating passively, making hypothetical driving decisions that are not executed. A shadow driver is one or more autonomous driving models of the ADS operating passively and making the hypothetical driving decisions. The hypothetical driving decisions are computed according to input comprising one or more signals captured while a human driver drives a vehicle. Such hypothetical driving decisions may be compared to decisions that the human driver of the vehicle makes while the one or more signals are captured. Comparing computed driving data, computed by the ADS, to captured driving data collected while the vehicle is driven by the human driver allows evaluating and demonstrating the safety of the autonomous functionality of the ADS.

### SUMMARY OF THE INVENTION

It is an object of some embodiments described in the present disclosure to provide a system and a method for generating a driving assistant model for assisting one or more autonomous driving models in operating one or more autonomous systems, for example one or more autonomous vehicles by training the driving assistant model, using simulated driving data generated using one or more permutations of an initial semantic driving scenario, to provide one or more driving instructions to one or more autonomous driving models while the one or more autonomous driving models are operating. Using a driving assistant model communicating with the one or more autonomous driving models while the one or more autonomous driving models are operating increases accuracy of the operation of the one or more autonomous driving models, increasing safety of an autonomous vehicle operated using the autonomous driving model. Furthermore, this allows increasing safety of the autonomous vehicle without depending on an ability to update the one or more autonomous driving models installed in the vehicle. Using one or more permutations of a semantic driving scenario to generate simulated driving data to train the driving assistant model facilitates generating finely nuanced simulated driving data, and additionally facilitates controlling differences between driving scenarios compared to randomly generating the driving scenarios. This allows training the driving assistant model in scenarios having minute differences from one another and additionally or alternatively specifically identified differences from one another, increasing accuracy of the driving assistant model and thus increasing safety of an autonomous vehicle operated using an autonomous driving model assisted by the driving assistant model.

The foregoing and other objects are achieved by the features of the independent claims. Further implementation forms are apparent from the dependent claims, the description and the figures.

According to a first aspect, a method for generating a driving assistant model comprises: computing at least one semantic driving scenario by computing at least one permutation of at least one initial semantic driving scenario; providing the at least one semantic driving scenario to a simulation generator to produce simulated driving data describing at least one simulated driving environment; training a driving assistant model using the simulated driving data to produce a trained driving assistant model; and providing by the trained driving assistant model at least one driving instruction to at least one autonomous driving model while the at least one autonomous driving model is operating.

According to a second aspect, a system for generating a driving assistant model comprises at least one hardware processor configured to: compute at least one semantic driving scenario by computing at least one permutation of at least one initial semantic driving scenario; provide the at least one semantic driving scenario to a simulation generator to produce simulated driving data describing at least one simulated driving environment; train a driving assistant model using the simulated driving data to produce a trained driving assistant model; and execute the trained driving assistant model and at least one autonomous driving model, where the trained driving assistant model provides at least one driving instruction to the at least one autonomous driving model while the at least one autonomous driving model is operating.

According to a third aspect, a software program product for generating a driving assistant model comprises: a non-transitory computer readable storage medium; first program instructions for computing at least one semantic driving scenario by computing at least one permutation of at least one initial semantic driving scenario; second program instructions for providing the at least one semantic driving scenario to a simulation generator to produce simulated driving data describing at least one simulated driving environment; third program instructions for training a driving assistant model using the simulated driving data to produce a trained driving assistant model; and fourth program instructions for execute the trained driving assistant model and at least one autonomous driving model, where the trained driving assistant model provides at least one driving instruction to the at least one autonomous driving model while the at least one autonomous driving model is operating; wherein the first, second, third and fourth program instructions are executed by at least one computerized processor from the non-transitory computer readable storage medium.

With reference to the first and second aspects, in a first possible implementation of the first and second aspects at least one of the at least one permutation is computed by providing at least one of the at least one initial semantic driving scenario to a generative machine learning model trained to compute, in response to input comprising a semantic driving scenario, a permutation of the semantic driving scenario.

With reference to the first and second aspects, in a second possible implementation of the first and second aspects the method further comprises: in response to the at least one autonomous driving model receiving the at least one driving instruction providing input, by the at least one autonomous driving model, to at least one control circuit of a vehicle.

With reference to the first and second aspects, in a third possible implementation of the first and second aspects the system further comprises at least one digital communication network interface connected to the at least one hardware processor and the trained driving assistant model provides the at least one driving instruction to the at least one autonomous driving model via the at least one digital communication network interface. Optionally, the method further comprises receiving, by the trained driving assistant from the at least one autonomous driving model, driving data collected while the autonomous driving model is operating and providing the at least one driving instruction to the at least one autonomous driving model is in response to receiving the driving data from the at least one autonomous driving model. Providing the at least one driving instruction in response to driving data collected while the autonomous driving model is operating increases accuracy of the at least one driving instruction, increasing safety of the vehicle.

With reference to the first and second aspects, in a fourth possible implementation of the first and second aspects the method further comprises: accessing driving event data describing at least one driving event detected in other driving data collected during operation of at least one other autonomous driving model (shadow driver) in another vehicle driven by a human driver; and computing the at least one initial semantic driving scenario using the driving event data. Using an initial semantic driving scenario computed using driving event driver collected during operation of a shadow driving in another vehicle driven by a human driver allows creating a driving scenario where performance of a shadow driver was not as expected and training the driving assistant model to provide more accurate output in response to such a scenario, thus increasing safety of a vehicle in which is installed an autonomous driving model assisted by the driving assistant model. Using a semantic driving scenario allows easier modification of one or more elements of a driving scenario while still preserving coherence of the driving scenario compared to other representations of the driving scenario, for example a detailed geometrical description. Optionally, the driving event data comprises one or more of: at least one signal, captured while the other vehicle is driven by the human driver, by at least one sensor installed in the other vehicle; captured driving data collected while the other vehicle is driven by the human driver and while the at least one signal is captured; and computed driving data computed by the shadow driver, using the at least one signal, while the other vehicle is driven by the human driver. Using at least one signal allows computing the initial semantic driving scenario using input similar to input that was available to the shadow driver, increasing accuracy of the simulated driving data produced based on a permutation of the initial semantic driving scenario. Using captured driving data and additionally or alternatively computed driving data increases accuracy of the initial semantic driving scenario in representing the one or more driver events, thus increasing likelihood of the simulated driving data that was produced based on a permutation of the initial semantic driving scenario representing a scenario which requires training, thus increasing accuracy of the driver assistant model trained using the simulated driving data. Optionally, the driving event data further comprises annotation data describing one or more relations between the at least one signal, the captured driving data and the computed driving data. Optionally, computing the at least one initial semantic driving scenario is further using at least one object identified in the at least one signal and not identified in the computed driving data, and the at least one initial semantic driving scenario comprises the at least one object. Computing an initial semantic driving scenario using one or more objects identified in the one or more signals and not identified in the computed driving data increases a likelihood that the simulated driving data that was produced based on a permutation of the initial semantic driving scenario represents a scenario which requires training, thus increasing accuracy of the driver assistant model trained using the simulated driving data. Optionally, the method further comprises identifying the at least one object in the at least one signal. Optionally, the annotation data comprises an indication of at least one object identified in the at least one signal and not identified in the computed driving data. Optionally, computing the at least one permutation comprises changing at least one property of the at least one object. Changing one or more properties of one or more objects identified in the one or more signals and not identified in the computed data increases a likelihood of generating a permutation driving scenario that represents a scenario which requires training, thus increasing accuracy of the driver assistant model trained using the simulated driving data. Optionally, the at least one sensor comprises at least one of: a camera, an electromagnetic radiation sensor, a microphone, a thermometer, an acceleration sensor, a rolling shutter camera, a velocity sensor, an audio sensor, a radio detection and ranging sensor (radar), a laser imaging, detection, a ranging sensor (LIDAR), an ultrasonic sensor, a thermal sensor, and a far infra-red (FIR) sensor and a video camera.

With reference to the first and second aspects, in a fifth possible implementation of the first and second aspects the simulated driving data comprises a plurality of synthetic signals, each simulating one of a plurality of signals captured from at least one physical driving environment equivalent to the at least one simulated driving environment by a plurality of sensors mounted on yet another vehicle while traversing the at least one physical driving environment. Optionally, the simulated driving data comprises a ground truth of the at least one simulated driving environment.

With reference to the first and second aspects, in a sixth possible implementation of the first and second aspects the method further comprises validating the driving assistant model using the simulated driving data to produce the trained driving assistant model, additionally or alternatively to training the driving assistant model using the simulated driving data. Optionally, the method further comprises verifying the driving assistant model using the simulated driving data to produce the trained driving assistant model, additionally or alternatively to training the driving assistant model using the simulated driving data. Optionally, the method further comprises testing the driving assistant model using the simulated driving data to produce the trained driving assistant model, additionally or alternatively to training the driving assistant model using the simulated driving data. Using the simulated driving data produced using the one or more permutation driving scenarios to validated the driving assistant model, test the driving assistant model, verify the driving assistant model, or any combination thereof, additionally or alternatively to training the driving assistant model increases accuracy of the driving assistant model compared to using only randomly generated driving scenarios.

With reference to the first and second aspects, in a seventh possible implementation of the first and second aspects the method further comprises: training a generative rendition model to generate at least one digital image according to at least one physical constraint by providing the generative rendition model with a plurality of training examples, each comprising a plurality of physical constraints of a simulated driving environment and a real digital image corresponding to the plurality of physical constraints, to produce a trained generative rendition model; and providing the simulated driving data to the driving assistant model for the purpose of one or more of: training the driving assistant model, verifying the driving assistant model, testing the driving assistant model and validating the driving assistant model. Optionally, producing the simulated driving data comprises computing at least one synthetic digital image using the trained generative rendition model by providing the trained generative rendition model with another plurality of physical constraints of another simulated driving environment. Training a generative rendition model using a plurality of physical constraints and a real digital image corresponding to the plurality of physical constraints increases realism, and thus accuracy, of an output of the generative rendition model. Training a driving assistant model, verifying the driving assistant model, validating the driving assistant model, testing the driving assistant model, or any combination thereof, using simulated driving data generated by a generative rendition model trained as described above increases accuracy of an output of the driving assistant model. Optionally, the plurality of physical constraints comprise a plurality of three-dimensional (3D) placements of a plurality of objects in the simulated driving environment. Optionally, the other plurality of physical constraints comprises another plurality of 3D placements of another plurality of objects in the other simulated driving environment. Optionally, the plurality of physical constraints comprises text in at least one natural language. Optionally, the other plurality of physical constraints comprises another text in the at least one natural language. Using text in a natural language to describe a physical constraint increases case of generating the one or more synthetic images compared to describing the physical constraint using some other methods, for example using a formal language. Optionally, the generative rendition model is a previously-trained generative rendition model, trained to generate at least one synthetic digital image in response to data describing an image, the previously-trained generative rendition model trained using a plurality of real digital images. Training a previously trained generative rendition model to respond to input comprising a plurality of physical constraints reduces an amount of time to train the generative rendition model, reducing cost of development. Optionally, the data describing the image is provided in a natural language. Describing the image in a natural language increases case of generating the one or more synthetic images compared to some other methods of describing an image, for example using a formal language. Optionally, the generative rendition model is a latent diffusion deep neural network. Optionally, generating the simulated driving data comprises providing the trained generative rendition model with at least one environment-characteristic adjustment value. Generating simulated driving data using one or more environment characteristic adjustment values allows generating one or more driving scenarios in a plurality of environment conditions, for example a plurality of weather conditions, reducing an amount of time and amount of resources required to increase accuracy of a trained autonomous driving model or driving assistant model, compare to using, for example, random driving scenarios.

With reference to the first and second aspects, in an eighth possible implementation of the first and second aspects the at least one initial semantic driving scenario is computed using driving event data describing at least one driving event detected in other driving data collected during operation of at least one other autonomous driving model (shadow driver) in a vehicle driven by a human driver, where at least one sensor is installed in the vehicle in an identified configuration, where the at least one autonomous driving model is installed in another vehicle, and where at least one other sensor is installed in the other vehicle in the identified configuration. Using a common identified configuration for the one or more other sensors installed in the other vehicle in which the one or more autonomous driving model is installed and the one or more sensors installed in the vehicle from which driving event data is used to generate the simulated training data for training the driving assistant model increases accuracy of the one or more driving instructions computed by the driving assistant model compared to other instructions generated by another model trained using other driving event data comprising one or more other signals collected by one or more yet other sensors installed in another configuration, different from the identified configuration.

With reference to the first and second aspects, in a ninth possible implementation of the first and second aspects the trained driving assistant model is installed in the vehicle. Installing the trained driving assistant model in the vehicle improves the safety of the vehicle, without relying on communication with a trained driving assistant installed remotely to the vehicle.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

Unless otherwise defined, all technical and/or scientific terms used herein have the same meaning as commonly understood by one of ordinary skill in the art to which embodiments pertain. Although methods and materials similar or equivalent to those described herein can be used in the practice or testing of embodiments, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

Some embodiments are herein described, by way of example only, with reference to the accompanying drawings. With specific reference now to the drawings in detail, it is stressed that the particulars shown are by way of example and for purposes of illustrative discussion of embodiments. In this regard, the description taken with the drawings makes apparent to those skilled in the art how embodiments may be practiced.

In the drawings:

FIG. 1 is a schematic block diagram of an exemplary system, according to some embodiments;

FIG. 2 is a schematic block diagram of another exemplary system, according to some embodiments;

FIG. 3 is a flowchart schematically representing an optional flow of operations for generating a driving assistant model, according to some embodiments;

FIG. 4 is a flowchart schematically representing an optional flow of operations for producing a semantic driving scenario, according to some embodiments;

FIG. 5 is a flowchart schematically representing an optional flow of operations for using driver event data, according to some embodiments; and

FIG. 6 is a flowchart schematically representing an optional flow of operations for generative rendition using physical constraints, according to some embodiments.

### DESCRIPTION OF SPECIFIC EMBODIMENTS OF THE INVENTION

As used herein, the term “interesting driving scenario” is used to mean an unusual driving scenario, that is a driving scenario that is unlikely, i.e. relatively rare, but possible. An interesting driving scenario is sometimes known as an edge-case scenario. One example of an interesting driving scenario is a near-collision, for example, when one vehicle moves quickly and closely to another vehicle. Other examples of an interesting driving scenario include an object on the road, unusual pedestrian behavior, unusual cyclist behavior, an abrupt stop of a vehicle (possibly followed by an unusual reaction by another vehicle), and an abrupt change in a vehicle's steering, for example when a vehicle abruptly steers towards a static object, for example a sidewalk or a building. Other examples of an interesting driving scenario include extreme weather conditions, some examples being fierce wind, a heavy downpour of rain, and a sudden bolt of lightning. When developing a system that responds to a driving scenario, for example an ADS or an ADAS, providing the system with interesting driving scenarios during training, testing, validation, verification and any combination thereof, increases robustness of the system. In addition to the need to generate photo-realistic synthetic data, there is a need to generate interesting simulated driving scenarios.

In machine learning, increasing an amount of datasets used to train a machine learning model typically increases accuracy of an output of the machine learning model. When capturing driving scenarios from real driving environments (henceforth referred to as real driving scenarios), most of the real driving scenarios are of likely scenarios, not edge-cases. As a result, a system trained by real driving scenarios is expected to become proficient in responding to the likely scenarios—of which there are many—but may perform poorly in response to an edge-case scenario, as the system was trained with relatively fewer data sets representing an edge-case.

Henceforth, the terms “edge-case” and “interesting scenario” are used interchangeably, both used to mean an unlikely but possible scenario.

One possible means of increasing an amount of interesting scenarios is increasing an amount of real driving scenarios. A cost of increasing the amount of real driving scenarios may be prohibitive, possibly requiring dozens of test vehicles on the road and additionally or alternatively taking many years to collect. In addition, increasing the amount of real driving scenario may not increase the amount of interesting scenarios sufficiently, for example in the summer it may not be possible to capture a heavy downpour of rain. Again, capturing sufficient driving scenarios may require an extended amount of time, spanning at least several months, and additionally or alternatively spanning many locations.

Another possible means of increasing the amount of interesting scenarios is by generating simulated interesting driving scenarios. Multiple simulated driving scenarios may be produced by using variations on static objects of a driving environment, dynamic objects of the driving environment, and environmental conditions, for example weather conditions and additionally or alternatively light conditions. There is an expectation that a large amount of simulated driving scenarios, generated using a large amount of variations, will include many interesting driving scenarios. However, there is no guarantee that a collection of generated simulated driving scenarios, whether generated randomly or according to a procedure, will provide sufficient coverage of possible interesting driving scenarios to guarantee that an autonomous driving model trained therewith will be robust.

Comparing the computed driving data, computed by the shadow driver, to the captured driving data collected while the vehicle is driven by the human driver allows identifying discrepancies between driving decisions made by the human driver and driving decisions made by the shadow driver. Such discrepancies are considered failures of the shadow driver, and there is a need to increase accuracy of the ADS's response to driving scenarios where such discrepancies occurred.

There exists a practice in the current autonomous driving industry to identify shadow driver failures and to annotate driving data pertaining to the shadow driver failure. For example, analysis of the driving data may include identifying one or more objects in the one or more signals that is not identified in the computed driving data that the shadow driver computes. Annotation of the driving data may include an indication of the one or more objects identified in the one or more signals and not identified in the computed driving data.

While quality of autonomous driving models is increasing rapidly, there still exist some known limitations to autonomous driving models installed in an ADS. One known limitation is the size of an autonomous driving model. Various considerations, including cost, power consumption and heat dissipation considerations, limit the size of memory and additionally or alternatively the amount of processing power available on the vehicle for executing an autonomous driving model. As a result, a server executing outside of an autonomous vehicle may be able to execute a larger model than those executed on the autonomous vehicle, capable of more accurate computations than computations made by the models executed on the autonomous vehicle. In addition, once an autonomous driving model is installed in an autonomous vehicle, updating the autonomous driving model may be challenging. Implementing a seamless update mechanism is challenging, as it requires ensuring that updates are delivered securely, without interruption to vehicle operation, and with minimal risk of cyber threats, for example when using over-the-air (OTA) updates. As a result, while a manufacturer of an ADS may have an updated version of an autonomous driving model installed in an autonomous vehicle, for example an autonomous driving model further trained using new training data that became available after installing the autonomous driving model in the autonomous vehicle, the updated version may not be installed in the autonomous vehicle. Deploying an updated model on a server external to the autonomous vehicle is typically easier than updating an autonomous driving model installed in an autonomous vehicle.

The present disclosure, in some embodiments described herewithin, proposes using a trained driving assistant model to assist one or more autonomous driving models in operating one or more autonomous systems, for example one or more autonomous vehicles. In such embodiments, the present disclosure proposes training the driving assistant model and using the trained driving assistant model to provide one or more driving instructions to one or more autonomous driving models while the one or more autonomous driving models are operating. Communication between the one or more autonomous driving models and the driving assistant model increases accuracy of the operation of the one or more autonomous driving models, increasing safety of an autonomous vehicle operated using the autonomous driving model. Further in such embodiments, the present disclosure proposes training the driving assistant model using one or more simulated driving environments produced according to one or more semantic driving scenarios, where the one or more semantic driving scenarios are one or more permutations of one or more initial semantic driving scenarios. Using one or more permutations of a semantic driving scenario reduces an amount of computation resources required to generate a variety of semantic driving scenarios compared to randomly generating each of the variety of semantic driving scenarios, increasing accuracy of an output of a model trained using the one or more permutations of the semantic driving scenario while reducing cost of development of the model. The model may be a driving assistant model. The model may be an autonomous driving model of an ADS.

In addition, the present disclosure, in some embodiments described herewithin, proposes using data that describes historical driving events to generate simulated driving scenarios for generating synthetic data for training a model. The model may be an autonomous driving model of an ADS. The model may be a driving assistant model, to assist one or more ADSs. More specifically, the present disclosure proposes, in some embodiments described herewithin, generating the simulated driving scenarios using driver events that are shadow driver failures. Training a model for an ADS or for assisting an ADS with training data generated based on shadow driver failures increases accuracy of the model's response to a driving scenario similar to a scenario where the shadow driver failure occurred, thus increasing reliability and usability of the model.

The present disclosure, in some embodiments, proposes using driving event data that describes driving events comparing the shadow driver to the human driver to generate driving scenarios. The present disclosure proposes, in some embodiments, accessing driving event data that describes one or more driving events detected in driving data that is collected during operation of a shadow driver in a vehicle driven by a human driver. A driving event may be a discrepancy between a driving decision made by the shadow driver and a driving decision made by the human driver.

Optionally, the driving event data comprises one or more signals captured while the vehicle is driven by the human driver, and captured driving data captured while the vehicle is driven by the human driver and while the one or more signals are captured. The captured driving data may include one or more of: the vehicle's velocity, the vehicle's acceleration, the vehicle's deceleration, and a steering operation. A steering operation may include a steering angle and additionally or alternatively duration of the steering operation. Optionally, the driving event data comprises computed driving data, computed by the shadow driver using the one or more signals. The captured driving data is indicative of driving decisions made by the human driver while the one or more signals are captured. Optionally, the computed driving data comprises one or more objects detected by the shadow driver. Some examples of an object include a traffic sign, a traffic signal, a marking on a road, another vehicle, a pedestrian, and an obstacle on the road. Optionally a detected object is detected incorrectly, i.e. an object in the computed driving data is different from the corresponding object in the one or more signals. Optionally, the computed driving data comprises one or more properties of a detected object, for example, an estimated velocity of the detected object and an estimated direction in which the detected object is moving. Optionally, the computed driving data comprises one or more driving commands, computed by the shadow driver in response to the one or more signals. The one or more driving commands are indicative of hypothetical driving decisions made by the shadow driver.

Optionally, the driving event data comprises annotation, describing one or more relations between the one or more signals, the captured driving data and the computed driving data. Such one or more relations may be indicative of a shadow driver failure. For example, when a human driver breaks the vehicle because of an obstacle on the road and the shadow driver continues accelerating, the one or more signals may include the obstacle, the captured driving data may be indicative of deceleration of the vehicle and the computed driving data may not include detection of the object and may not include a change in the vehicles velocity or steering. The relationship between the obstacle detected in the one or more signal and the lack thereof in the computed driving data, together with the deceleration identified in the captured driving data and lack thereof in the computed driving data may be indicative of a driving event that is a shadow driver failure.

Further, in such embodiments, the present disclosure proposes computing one or more simulated driving scenarios using the driving event data. Optionally, a simulated driving scenario is a semantic three-dimensional (3D) driving scene, comprising a plurality of objects that can be manipulated. This is in contrast to a set of pixels describing the driving scene. Optionally, the simulated driving scenario comprises one or more objects that the shadow driver failed to detect, i.e. one or more objects identified in the one or more signals and not identified in the computed driving data.

Optionally, the one or more simulated driving scenarios are provided to a simulation generator to produce simulated driving data describing one or more simulated driving environments.

Optionally, the simulated driving data is provided to one or more ADSs, optionally to train the ADS, i.e. train one or more machine learning models of the ADS. Optionally, the simulated driving data is provided additionally or alternatively for the purpose of one or more of: verifying the ADS, validating the ADS and testing the ADS. Optionally, the simulated driving data is provided to a driving assistant model, optionally to train the driving assistant model. Optionally, the simulated driving data is provided additionally or alternatively for the purpose of one or more of: verifying the driving assistant model, validating the driving assistant model and testing the driving assistant model.

As described above, producing the simulated driving data may comprise applying one or more permutations to the one or more simulated driving scenarios. For example, a 3D placement of an object in a scenario may be changed. Other examples of a permutation include changing a size of an object, changing an orientation of an object, and changing a physical property of an object, for example a color or a material. Optionally, applying a permutation to a simulated driving scenario comprises applying at least one environment characteristic adjustment, for example changing a lighting property or a weather condition.

Optionally, the driving event data is retrieved from a database. Optionally, the driving event data is retrieved from the cloud, using a digital data communication network, for example the Internet. Optionally, the vehicle is a connected vehicle such that the one or more signals and additionally or alternatively the captured driving data and additionally or alternatively the computed driving data is sent by the vehicle to at least one network storage using a digital communication network, for example a cellular network.

Optionally, the shadow driver operates independently of the vehicle, for example on a processor that is not installed in the vehicle. In such embodiments, the shadow driver uses the one or more signals that are captured while the vehicle is driven by the human driver to compute the computed driving data, however this is done offline, after the human driver drives the vehicle.

Optionally, the vehicle comprises one or more sensors installed in an identified configuration. The identified configuration may include an identified location in the vehicle for each of the one or more sensors. Optionally, the identified configuration includes an identified orientation for at least one of the one or more sensors. Optionally, the identified configuration includes one or more settings of at least one of the one or more sensors. Optionally, a model for an ADS or for assisting an ADS is trained using the simulated driving data comprises the one or more sensors in the identified configuration. Training the model using data generated based on a shadow driver operating in a vehicle with the same one or more sensors in the same identified configuration increases the likelihood of increasing the accuracy of the model, thus increasing reliability and usability of the model.

As the use of perception systems increases, so does the need for data for training perception systems. Some perception systems are trained using synthetically generated simulated environments. When generating synthetic data for training or testing a model such as an ADS or a driving assistant model there is a need to generate data that exhibits a realistic look, for example for visual sensors. A photo-realistic synthetic image is an image that looks as though it were photographed by a camera. A rendering engine can generate a synthetic image according to semantic descriptions of the required image. However, many images generated by a rendering engine will not appear photo-realistic. Some characteristics that cause an image to appear non-realistic are: color saturation in some areas of the image; gradients (or lack thereof) in the color of the sky, a road, or any other surface in the image; and lighting and shading.

In the field of computer graphics, the term rendering refers to the process of generating a digital image from a model describing the image. The model may be 2D or 3D. A model describing an image typically comprises a set of objects and one or more physical constraints regarding placement of the objects in the image. For example, a distance between objects or a distance between an object and a location of a sensor from which the image could be captured. For clarity, henceforth the term image model is used to mean a model describing an image.

In the field of machine learning, a generative model is a machine learning model that can generate a new data instance. This is in contrast with a discriminative model that discriminates between different types of data instances. Thus, the term generative rendering model (or generative rendition model) refers to a machine learning model that can generate a new image according to input comprising an image model of an image. A generative rendition model may be a neural network model.

There exist generative models, trained with extremely large data sets, which generate photo-realistic images. Some such models respond to input in a natural language (i.e. the image model describing the image is provided in a natural language, for example “a person sitting in a car”). However, existing generative rendition models cannot apply physical constraints to objects in the generated image. For example, while an image model provided to some existing procedural renderers may include a constraint indicative of a person 50 meters away from the camera capturing the image, current generative rendering models cannot guarantee that a generated image complies with such a constraint.

There is a need for synthetic data generated for use with autonomous driving models and additionally or alternatively for use with driving assistant models to be generated according to one or more physical constraints, for example to validate an autonomous system's compliance with one or more safety regulations. While procedural rendition can comply with physical constraints, the characteristics of images rendered by such procedural renderers are limited. For example, a procedural renderer may render an urban driving scenario according to a given weather condition, such a procedural renderer may not be able to render an image that has environmental characteristics of a given city, for example Paris or New Delhi. Encoding such a variety of characteristics in a procedural renderer is cost-prohibitive.

On the other hand, a generative rendering model may be trained to produce any number of environment characteristics. Thus, the present disclosure proposes, in some embodiments described herewithin, training a generative rendering model to apply physical constraints to generated images. To do so, the present disclosure proposes, in some embodiments described herewithin, to train the generative rendition model by providing the generative rendition model with a plurality of training examples where each training example comprises a plurality of physical constraints and a real digital image that corresponds to the plurality of physical constraints. Optionally, the plurality of physical constraints are a plurality of physical constraints of a simulated driving environment. A real digital image is an image captured by a sensor in a physical location. It may not be possible to find a digital image that corresponds exactly to the plurality of physical constraints. Optionally, the real digital image corresponds to the plurality of physical constraints according to one or more compliance tests applied to the plurality of physical constraints and the respective real digital image associated therewith. Optionally, the plurality of training examples further include for at least one training example a ground truth of the simulated driving environment. Using a generative rendition model trained using a plurality of physical constraints allows increasing a variety of driving scenarios provided to a model for an ADS or for assisting an ADS for training, validation, verification, and/or testing thereof, including increasing a variety of environment characteristics for an identified set of physical constraints, thus increasing accuracy and usability of the model.

Optionally, a trained generative rendering model trained as described above, using a plurality of training sets each comprising a plurality of physical constraints and a real digital image, is used to compute one or more synthetic digital images. Optionally, the trained generative rendering model is provided with another plurality of physical constraints of another simulated driving environment to compute the one or more synthetic digital images. Optionally, the trained generative rendering model is further provided with another ground truth of the other simulated driving environment. Optionally, the one or more synthetic digital images are provided to one or more autonomous driving models of an ADS for training the ADS. Additionally, or alternatively, the one or more synthetic digital images are provided to the ADS for one or more of: testing the autonomous driving model, validating the autonomous driving model and verifying the autonomous driving model. Additionally, or alternatively, the one or more synthetic digital images are provided to a driving assistant model for one or more of: training the driving assistant model, testing the driving assistant model, validating the driving assistant model and verifying the driving assistant model. Optionally, the one or more synthetic digital images are provided with the other ground truth of the other simulated driving environment.

Optionally, the generative rendition model is a previously trained generative rendition model, trained to generate one or more synthetic digital images using a plurality of real digital images. Training, using physical constraints, a previously trained generative rendition model trained using a plurality of real digital images increases photo-realism of the one or more synthetic digital images produced by the generative rendition model after being trained using physical constraints compared other synthetic digital images produced by the previously trained generative rendition model, thus increasing accuracy of a model trained using simulated driving data comprising the one or more synthetic digital images.

Optionally, the generative rendition model is trained to generate the one or more synthetic digital images according to one or more environment characteristics, for example a weather condition, a lighting condition or a characteristic indicative of an identified geographical location, for example Paris, New York or New Delhi. Optionally, the previously trained generative rendition model is trained to generate the one or more synthetic images according to the one or more environment characteristics. Optionally, the previously trained generative rendition model is trained using data describing an image in a natural language.

Optionally, the generative rendering model is a latent diffusion deep neural network. Using a latent diffusion deep neural network allows increasing accuracy of a trained model when training a machine learning model having a latent variable with high dimensionality (that is, a random variable that cannot be observed neither in training nor in a test phase testing a machine learning model). Using a machine learning model having a latent variable with high dimensionality facilitates increasing accuracy of an output of the model in a large amount of metrics. In synthetic digital image rendition, this allows generative rendition of synthetic images that are more photo-realistic than images rendered by a model having a latent variable with fewer dimensions.

Optionally, a physical constraint is a 3D placement of an object in the simulated driving environment. Thus, optionally the plurality of physical constraints of a training example comprises a plurality of 3D placements of a plurality of objects in the simulated driving environment. Similarly, the other plurality of physical constraints provided to the trained generative rendering model is another plurality of 3D placements of another plurality of objects in the other simulated driving environment. Optionally, a 3D placement of an object is relative to a simulated camera position for capturing the generated image. Optionally, a 3D placement of an object is relative to another object. Optionally, a training example comprises a ground truth of the simulated driving environment.

Optionally, the plurality of 3D placements are generated by a simulation engine, according to a semantic 3D scenario, for example a semantic 3D scenario based on driver event data as described above. Optionally, the simulation engine further generates a ground truth of the simulated driving environment. Optionally, the plurality of physical constraints are expressed in a formal language, for example extensible Markup Language (XML) and JavaScript Object Notation (JSON), or any other formal syntax. Optionally, the plurality of physical constraints comprises text in one or more natural languages. Similarly, the other plurality of physical constraints may be expressed in a formal language, and additionally or alternatively in one or more natural languages.

Optionally, a training example comprises a real digital image annotated with indications of 3D physical constraints.

There may be a need to generate simulated driving data according to an identified environment characteristic. Optionally, generating the simulated driving data comprises providing the trained generative rendering model with one or more environment-characteristic adjustment values. Some examples of an environment-characteristic adjustment value are a value indicative of a weather characteristic, such as cloudiness, windiness and humidity, a time of year, and a value indicative of an identified geographical location.

Before explaining at least one embodiment in detail, it is to be understood that embodiments are not necessarily limited in its application to the details of construction and the arrangement of the components and/or methods set forth in the following description and/or illustrated in the drawings and/or the Examples. Implementations described herein are capable of other embodiments or of being practiced or carried out in various ways.

Embodiments may be a system, a method, and/or a computer program product. The computer program product may include a computer readable storage medium (or media) having computer readable program instructions thereon for causing a processor to carry out aspects of the embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an crasable programmable read-only memory (EPROM or Flash memory), a static random access memory (SRAM), a portable compact disc read-only memory (CD-ROM), a digital versatile disk (DVD), a memory stick, a floppy disk, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of embodiments may be assembler instructions, instruction-set-architecture (ISA) instructions, machine instructions, machine dependent instructions, microcode, firmware instructions, state-setting data, or either source code or object code, natively compiled or compiled just-in-time (JIT), written in any combination of one or more programming languages, including an object oriented programming language such as Smalltalk, C++, Java, Object-Oriented Fortran or the like, an interpreted programming language such as JavaScript, Python or the like, and conventional procedural programming languages, such as the “C” programming language, Fortran, or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), a coarse-grained reconfigurable architecture (CGRA), or programmable logic arrays (PLA) may execute the computer readable program instructions by utilizing state information of the computer readable program instructions to personalize the electronic circuitry, in order to perform aspects of embodiments.

Aspects of embodiments are described herein with reference to flowchart illustrations and/or block diagrams of methods, apparatus (systems), and computer program products according to embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

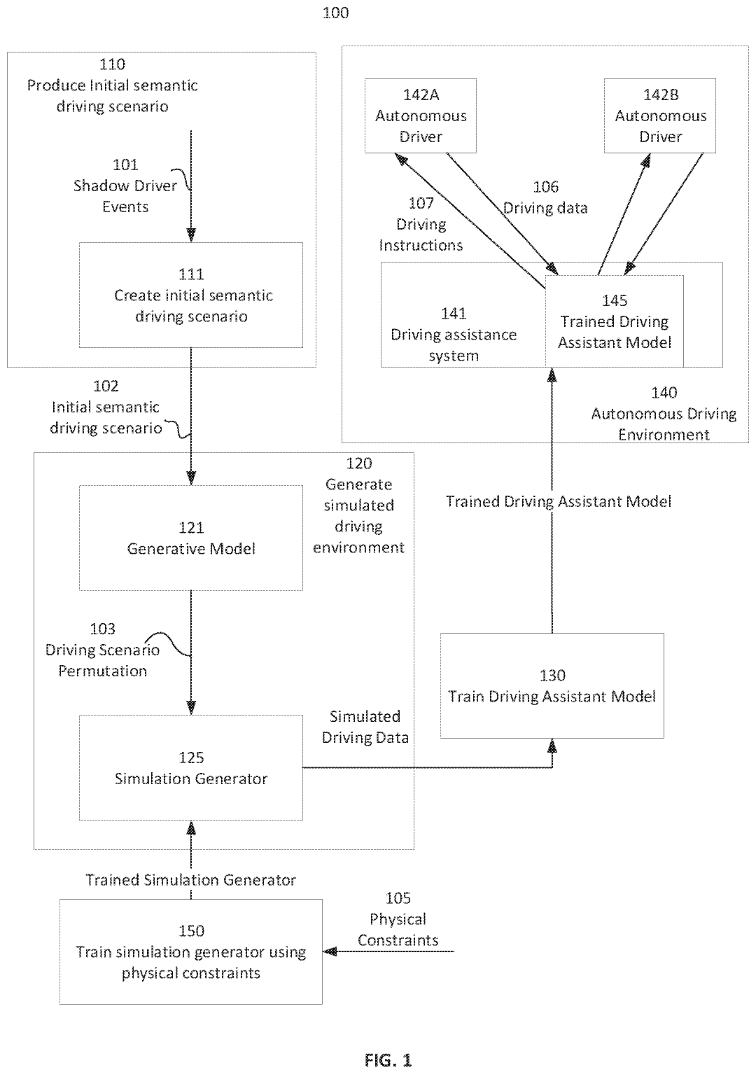

Reference is now made to FIG. 1, showing a schematic block diagram of an exemplary system 100, according to some embodiments. FIG. 1 focuses on functional components of a system according to some embodiments. In such embodiments, the system comprises sub-system 130 for training a driving assistant model. Additionally or alternatively, sub-system 130 is for training one or more autonomous driving models of an ADS. In such embodiments, a model trained by training sub-system 130 is trained using simulated training data describing one or more simulated driving environments produced by simulation generator 125 of generation sub-system 120. Optionally, simulation generator 125 is a previously-trained generative rendition model, trained to generate one or more synthetic digital images in response to data describing the image. Optionally, simulation generator 125 is previously trained using a plurality of real digital images, where a real digital image is captured by a sensor in a physical environment. Optionally, the data describing the image is provided in a natural language. Optionally, simulation generator 125 is a latent diffusion deep neural network.

Optionally, simulation generator 125 produces the simulated driving data in response to one or more semantic driving scenarios 103 provided thereto. Optionally, the one or more semantic driving scenarios 103 are one or more permutations of initial semantic driving scenario 102. Optionally, the one or more semantic driving scenarios 103 are generated by one or more generative machine learning model 121 in response to input comprising one or more initial semantic driving scenario 102. Optionally, generative machine learning model 121 is trained to compute, in response to input comprising a semantic driving scenario, a permutation of the semantic driving scenario. Optionally, the one or more semantic driving scenarios 103 are generated by providing the generative machine learning model 121, in each of a plurality of iterations, one of a plurality of initial semantic driving scenarios.

Further in such embodiments, trained driving assistant model 145 is provided by training sub-system 130 to driving assistance sub-system 141 of autonomous driving environment 140. Optionally, autonomous driving environment comprises one or more autonomous driving models, for example comprising autonomous driving model 142A and autonomous driving model 142B, collectively referred to as one or more autonomous driving models 142. For brevity, henceforth the term “autonomous driver” is used to mean “autonomous driving model” and the terms are used interchangeably.

Optionally, an autonomous driver is installed in an autonomous vehicle, for example when autonomous driving environment 140 is a physical environment. Optionally, an autonomous driver is executed by a hardware processor that is not installed in an autonomous vehicle, for example when autonomous driving environment 140 is a training environment for training the autonomous driver.

Optionally, autonomous drivers 142 communicate with trained driving assistant model 145. In an example, autonomous driver 142A sends training driving assistant model 145 driving data 106. Further in the example, training driving assistant model 145 sends autonomous driver 142A one or more driving instructions 107. Optionally, training driving assistant model 145 sends one or more driving instructions 107 in response to receiving driving data 106 from autonomous driver 142A.

Optionally, one or more initial semantic driving scenarios 102 are produced by production sub-system 110. Optionally, production sub-system 110 comprises component 111 for creating an initial semantic driving scenario using driving event data 101, where driving event data 101 describes one or more driving events detected in other driving data. Component 111 may comprise a processing circuitry. Optionally, component 111 comprises one or more component software objects.

Optionally, simulation generator 125 is trained by sub-system 150. Optionally, sub-system 150 trains simulation generator 125 using one or more physical constraints 105.

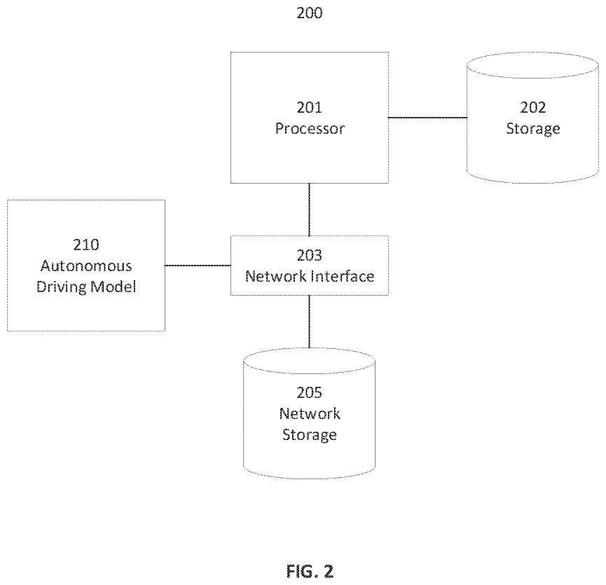

Reference is now made also to FIG. 2, showing a schematic block diagram of another exemplary system 200, according to some embodiments, optionally for implementing system 100. In such embodiments, at least one hardware processor 201 is connected to one or more digital communication network interface 203.

For brevity, henceforth the term “processing unit” is used to mean “at least one hardware processor” and the terms are used interchangeably. In addition, for brevity henceforth the term “network interface” is used to mean “at least one digital communication network interface” and the terms are used interchangeably.

Optionally, network interface 203 is connected to a wireless network, for example a Wi-Fi network, or a cellular communication network. Optionally, network interface 203 is connected to a wired digital communication network, for example an Ethernet network. Optionally, network interface 203 implements a near communication protocol, for example Bluetooth.

Optionally, one or more autonomous drivers 142 of FIG. 1 are implemented by one or more autonomous driving model 210, connected to processing unit 201, optionally via network interface 203. Optionally, autonomous driving model 210 is executed by one or more other processing circuitries (not shown), for example a processing circuitry of a vehicle or a processing circuitry executing an autonomous driver simulator.

Optionally, processing unit 201 is connected to digital storage, for example to access driver event data stored on the digital storage. Optionally, the digital storage comprises at least one non-volatile digital storage 202, directly connected to processing unit 201. Some examples of a non-volatile digital storage include a hard disk drive (HDD) and s solid-state drive (SSD). Optionally, the digital storage comprises at least one network storage 205, optionally connected to processing unit 201 via network interface 203. Optionally, the digital storage comprises one or more storage networks connected to processing unit 201 via network interface 203.

Optionally, processing unit 201 implements component 111 for creating an initial semantic driving scenario. Additionally or alternatively, processing unit 201 may implement at least part of generation sub-system 120, for example generative model 121 and additionally or alternatively simulation generator 125. Additionally or alternatively, processing unit 201 may implement sub-system 130 for training driving assistant model 145. Additionally or alternatively, processing unit 201 may implement sub-system 150 for training simulation generator 125. Additionally or alternatively, processing unit 201 may execute driving assistance system 141.

In some embodiments described herewithin, to generate trained driving assistant model 145 system 200 implements system 100 by implementing the following optional method.

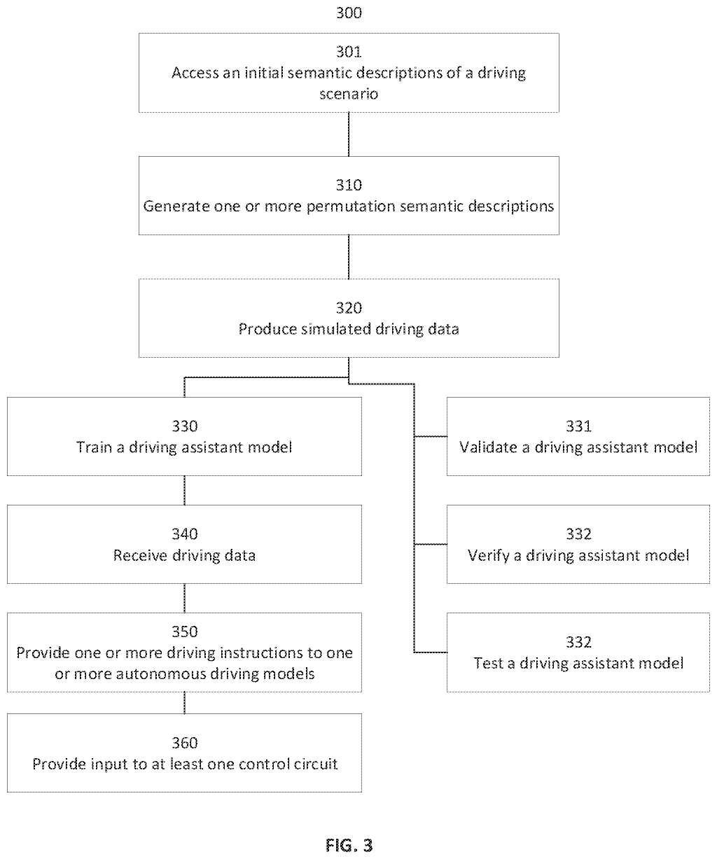

Reference is now made also to FIG. 3, showing an optional flow of operations 300 for generating a driving assistant model, according to some embodiments. In such embodiments, in 301 processing unit 201 accesses initial semantic driving scenario 102 and in 310 optionally computes one or more semantic driving scenario 103 by computing one or more permutations of one or more initial semantic driving scenario 102. Optionally, processing unit 201 computes one or more semantic driving scenario 103 by providing one or more initial semantic driving scenario 102 to generative model 121. Optionally, at least one semantic driving scenario of one or more semantic driving scenario 103 comprises a change in 3D placement of an object of one or more initial semantic driving scenario 102. Optionally, at least one semantic driving scenario of one or more semantic driving scenario 103 comprises a change of a size of an object of one or more initial semantic driving scenario 102. Optionally, at least one semantic driving scenario of one or more semantic driving scenario 103 comprises a change of an orientation of the object. Optionally, at least one semantic driving scenario of one or more semantic driving scenario 103 comprises a change of a physical property of the object, for example a color or a material. Optionally, applying a permutation to at least one of one or more initial semantic driving scenario 102 comprises applying at least one environment characteristic adjustment, for example changing a lighting property or a weather condition.

In 320, processing unit 201 optionally provides one or more semantic driving scenario 103 to simulation generator 125, to produce simulated driving data describing one or more simulated driving environments. Optionally, the simulated driving data comprises a plurality of synthetic signals, each simulating one of a plurality of signals captured from one or more physical driving environments that are equivalent to the one or more simulated driving environments. Optionally, a synthetic signal simulates a signal captured by a sensor mounted on a vehicle while traversing the one or more physical driving environments. Optionally, the simulated driving data comprises a ground truth of the one or more simulated driving environments. Optionally, the ground truth comprises semantic segmentation of a synthetic signal. Optionally, the ground truth comprises polygon annotation of a synthetic signal. Optionally, the ground truth comprises one or more 2D/3D bounding boxes for a synthetic signal, for example bounding one or more objects in the synthetic signal.

Optionally, 301, 310 and 320 are repeated in each of a plurality of iterations to produce the simulated driving data, i.e. in each iteration of the plurality of iterations in 301 processing unit 201 access one initial semantic driving scenario, in 310 processing unit 201 produces at least one driving scenario permutation of the initial semantic driving scenario and in 320 processing unit 201 produces at least part of the simulated driving data using the at least one driving scenario permutation.

In 330, processing unit 201 optionally trains a driving assistant model using the simulated driving data, to produce trained driving assistant model 145.

In 340, processing unit 201 implementing trained driving assistant model 145 optionally receives driving data 106 from autonomous drivers 142. Optionally, driving data 106 is collected while autonomous drivers 142 operate.

Optionally, in 350 processing unit 201 implementing trained driving assistant model 145 provides one or more driving instructions 107 to autonomous drivers 142, optionally while autonomous drivers 142 are operating. Optionally, processing unit 201 provides the one or more driving instructions 107 in response to receiving driving data 106. Optionally, the driving data 106 comprises one or more signals captured while autonomous drivers 142 are operating. The driving data 106 may include one or more of: a vehicle's velocity, a vehicle's angular velocity, a wheel velocity, a vehicle's acceleration, a vehicle's deceleration, a global positioning system (GPS) location, and a steering operation. A steering operation may include a steering angle and additionally or alternatively duration of the steering operation. Optionally, the driving data 106 comprises computed data, computed by the autonomous drivers 142 using the one or more signals. Optionally, the computed data comprises one or more objects detected by the autonomous drivers 142. Some examples of an object include a traffic sign, a traffic signal, a marking on a road, another vehicle, a pedestrian, and an obstacle on the road.

In 360, autonomous drivers 142 optionally provide input to one or more control circuits of a vehicle, optionally in response to receiving one or more driving instructions 107. Optionally, a control circuit operates an actuator of the vehicle. Some examples of an actuator of a vehicle include, but are not limited to, an accelerator, a break, a vehicle light and a horn. Some examples of a vehicle light are a head light, a tail light and a signal light. Optionally, a driving instruction comprises instructing a control circuit to change a brightness and additionally or alternatively a color of a vehicle light. Optionally, a driving instruction comprises instructing an accelerator to accelerate the vehicle, optionally comprising a duration and additionally or alternatively a throttle position of the accelerator. Optionally, a driving instruction comprises instructing a break to decelerate the vehicle, optionally comprising a duration of deceleration and additionally or alternatively a break force. Optionally, trained driving assistant model 145 is installed in each of autonomous drivers 142, in this example in autonomous driver 142A and autonomous driver 142B, each installation providing assistance to one autonomous driving model. Optionally, trained driving assistant model 145 is connected to autonomous drivers 142 via network interface 203, such that driving assistant model 145 provides driving assistance to more than one autonomous driving model.

Additionally or alternatively to training driving assistant model 145 in 330, in 331 processing unit 201 validates the driving assistant model. Additionally or alternatively, in 332 processing unit 201 verifies the driving assistant model. Additionally or alternatively, in 333 processing unit 201 tests the driving assistant model.

Optionally, processing unit 201 generates initial semantic driving scenario 102 that is accessed in 301. To do so, in some embodiments processing unit 201 executes the following optional method.

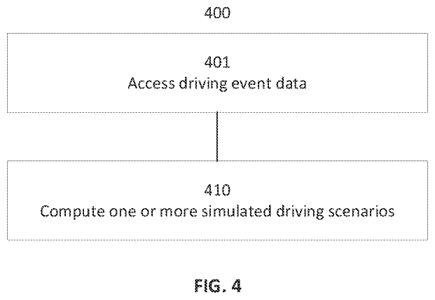

Reference is now made also to FIG. 4, showing a flowchart schematically representing an optional flow of operations 400 for producing a semantic driving scenario, according to some embodiments. In such embodiments, in 401 processing unit accessing driving event data 101. Optionally, driving event data 101 are stored on the digital storage, for example on at least one non-volatile digital storage 202 and additionally or alternatively on at least one network storage 205. Optionally, processing unit 201 produces at least part of driving event data 101.

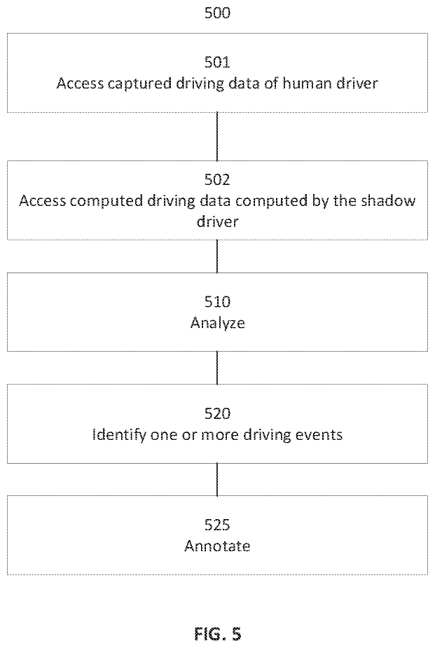

Reference is now made also to FIG. 5, showing an optional flow of operations 500 for using driver event data, according to some embodiments. In 501, processing unit 201 optionally accesses one or more signals, captured while another vehicle is driven by a human driver by one or more sensors installed in the other vehicle, and captured driving data, collected while the other vehicle is driven by the human driver and while the one or more signals are captured. In 502, processing unit 201 optionally accesses computed driving data computed by a shadow driver installed in the other vehicle using the one or more signals while the other vehicle is driven by the human driver. Optionally, the one or more signals are captured by sensor one or more sensors installed in an identified configuration in the other vehicle. Optionally, the identified configuration includes an identified orientation for at least one of the one or more sensors. Optionally, the identified configuration includes one or more settings of at least one of the one or more sensors. Optionally, one or more other sensors are installed in the vehicle executing autonomous drivers 142 in the identified configuration. Optionally the identified configuration includes a make of a sensor of the one or more sensors. Optionally, the identified configuration includes a position of the sensor.

Optionally, driving event data 101 include the one or more signals. Optionally, driving event data 101 include the captured driving data. Optionally, driving event data 101 include the computed driving data.

In 510, processing unit 201 optionally analyzes driving event data 111 and in 520 processing unit 201 optionally identifies one or more driving events. Optionally, a driving event is a discrepancy between a driving decision made by the shadow driver and a driving decision made by the human driver. In 525 processing unit 201 optionally adds annotation data describing one or more relations between the one or more signals, the captured driving data and the computed driving data. Optionally, the annotation data is added to the driving event data by an operator that is not processing unit 201, for example a human operator. One example of annotation data is an indication of an object that is identified in the one or more signals but not identified in the computed driving data, optionally indicative of an object present in a driving scene but undetected by the shadow driver, for example a road sign, a road signal or an obstacle. Other examples of annotation data include, but are not limited to, an error in a detection made by the shadow driver. Optionally at least some of the annotation data is indicative of the one or more driving events identified in 520. Optionally, analyzing the driving event data 111 in 510 comprises identifying one or more objects in the one or more signals that is not identified in the computed driving data.

Reference is now made again to FIG. 4. In 410, processing unit 201 implementing component 111 optionally computes one or more initial semantic driving scenario 102 using the driver event data 101, optionally enhanced using method 500. Optionally, computing the one or more initial semantic driving scenario 102 comprises using the one or more objects identified in the one or more signals and not identified in the computed driving data. Optionally, the one or more initial semantic driving scenario 102 comprise the one or more objects. Optionally, the one or more objects serve as an anchor for generating the one or more initial semantic driving scenario.

In some embodiments described herewithin, simulation generator 125 is trained to produce the simulated driving data in 320, where the training is by using one or more physical constraints. To train simulation generator 125, in such embodiments processing unit 201 implements the following optional method.

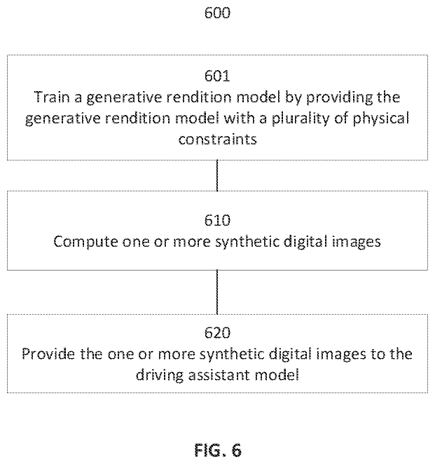

Reference is now made also to FIG. 6, showing a flowchart schematically representing an optional flow of operations 600 for generative rendition using physical constraints, according to some embodiments. In such embodiments, in 601 processing unit 201 implementing sub-system 150 trains simulation generator 125, optionally by providing simulation generator 125 with a plurality of training examples where each training example of the plurality of training example comprises a plurality of physical constraints and a real digital image. Optionally the plurality of physical constraints are a plurality of physical constraints of a simulated driving environment and the real digital image corresponds to the plurality of physical constraints. Optionally, the real digital image is a digital image captured by a sensor in a physical location. Optionally, the plurality of physical constraints comprise a plurality of 3D placements of a plurality of objects in the simulated driving environment. Some examples include a distance of an object from an identified location in the simulated driving environment, an orientation of an object in the simulated driving environment and a distance between two or more objects in the simulated driving environment. Optionally, a 3D placement is generated from a semantic 3D scenario. Optionally, the plurality of physical constraints comprises text in one or more natural languages, for example text describing a relative position of two objects or an orientation of an object.

Optionally, training simulation generator 125 produces a trained generative rendition model (trained generative model 125).

Optionally, in 610 processing unit 201 uses the trained generative rendition model to produce the simulated driving data, comprising computing one or more synthetic digital images. Optionally, computing the one or more synthetic digital images is by providing the trained generative rendition model with another plurality of physical constraints of another simulated driving environment. Optionally, the other plurality of physical constraints comprise another plurality of 3D placements of another plurality of objects in the other simulated driving environment. Optionally, the other plurality of physical constraints comprises another text in the one or more natural languages. Optionally, generating the simulated driving data comprises providing the trained generative rendition model (trained generative model 125) with one or more environment-characteristic adjustment values. Some examples of an environment-characteristic adjustment values include, but are not limited to, a weather characteristic, a time of year, a time of day, and a geographical location, for example a specific city.

In 620 processing unit 201 optionally provides the simulated driving data to the driving assistant model for the purpose of training thereof and producing trained driving assistant model. Additionally, or alternatively, the one or more synthetic digital images are provided to the driving assistant model for one or more of: testing the driving assistant model, validating the driving assistant model and verifying the driving assistant model.

Optionally, methods 300, 400, 500 and 600 are used, together or separately, when producing an autonomous driving model, for example autonomous drivers 142.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is expected that during the life of a patent maturing from this application many relevant models will be developed and the scope of the term model is intended to include all such new technologies a priori.

As used herein the term “about” refers to +10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment may include a plurality of “optional” features unless such features conflict.

Throughout this application, various embodiments may be presented in a range format. It should be understood that the description in range format is merely for convenience and brevity and should not be construed as an inflexible limitation on the scope of embodiments. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of embodiments, which are, for clarity, described in the context of separate embodiments, may also be provided in combination in a single embodiment. Conversely, various features of embodiments, which are, for brevity, described in the context of a single embodiment, may also be provided separately or in any suitable subcombination or as suitable in any other described embodiment. Certain features described in the context of various embodiments are not to be considered essential features of those embodiments, unless the embodiment is inoperative without those elements.

Although embodiments have been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A method for generating a driving assistant model, comprising:
computing at least one semantic driving scenario by computing at least one permutation of at least one initial semantic driving scenario;
providing the at least one semantic driving scenario to a simulation generator to produce simulated driving data describing at least one simulated driving environment;
training a driving assistant model using the simulated driving data to produce a trained driving assistant model; and
providing by the trained driving assistant model at least one driving instruction to at least one autonomous driving model while the at least one autonomous driving model is operating.

2. The method of claim 1, wherein at least one of the at least one permutation is computed by providing at least one of the at least one initial semantic driving scenario to a generative machine learning model trained to compute, in response to input comprising a semantic driving scenario, a permutation of the semantic driving scenario.

3. The method of claim 1, further comprising:
in response to the at least one autonomous driving model receiving the at least one driving instruction providing input, by the at least one autonomous driving model, to at least one control circuit of a vehicle.

4. The method of claim 3, wherein the trained driving assistant model is installed in the vehicle.

5. The method of claim 1, wherein the trained driving assistant model provides the at least one driving instruction to the at least one autonomous driving model via at least one digital communication network.

6. The method of claim 1, further comprising receiving, by the trained driving assistant from the at least one autonomous driving model, driving data collected while the autonomous driving model is operating;
wherein providing the at least one driving instruction to the at least one autonomous driving model is in response to receiving the driving data from the at least one autonomous driving model.

7. The method of claim 1, further comprising:
accessing driving event data describing at least one driving event detected in other driving data collected during operation of at least one other autonomous driving model (shadow driver) in another vehicle driven by a human driver; and
computing the at least one initial semantic driving scenario using the driving event data.

8. The method of claim 7, wherein the driving event data comprises one or more of:
at least one signal, captured while the other vehicle is driven by the human driver, by at least one sensor installed in the other vehicle;
captured driving data collected while the other vehicle is driven by the human driver and while the at least one signal is captured; and
computed driving data computed by the shadow driver, using the at least one signal, while the other vehicle is driven by the human driver.

9. The method of claim 8, wherein the driving event data further comprises annotation data describing one or more relations between the at least one signal, the captured driving data and the computed driving data.

10. The method of claim 8, wherein computing the at least one initial semantic driving scenario is further using at least one object identified in the at least one signal and not identified in the computed driving data; and
wherein the at least one initial semantic driving scenario comprises the at least one object.

11. The method of claim 10, further comprising identifying the at least one object in the at least one signal.

12. The method of claim 9, wherein the annotation data comprises an indication of at least one object identified in the at least one signal and not identified in the computed driving data.

13. The method of claim 10, wherein computing the at least one permutation comprises changing at least one property of the at least one object.

14. The method of claim 1, wherein the simulated driving data comprises a plurality of synthetic signals, each simulating one of a plurality of signals captured from at least one physical driving environment equivalent to the at least one simulated driving environment by a plurality of sensors mounted on yet another vehicle while traversing the at least one physical driving environment.

15. The method of claim 1, wherein the simulated driving data comprises a ground truth of the at least one simulated driving environment.

16. The method of claim 8, wherein the at least one sensor comprises at least one of: a camera, an electromagnetic radiation sensor, a microphone, a thermometer, an acceleration sensor, a rolling shutter camera, a velocity sensor, an audio sensor, a radio detection and ranging sensor (radar), a laser imaging, detection, a ranging sensor (LIDAR), an ultrasonic sensor, a thermal sensor, and a far infra-red (FIR) sensor and a video camera.

17. The method of claim 1, further comprising validating the driving assistant model using the simulated driving data to produce the trained driving assistant model, additionally or alternatively to training the driving assistant model using the simulated driving data.

18. The method of claim 1, further comprising verifying the driving assistant model using the simulated driving data to produce the trained driving assistant model, additionally or alternatively to training the driving assistant model using the simulated driving data.

19. The method of claim 1, further comprising testing the driving assistant model using the simulated driving data to produce the trained driving assistant model, additionally or alternatively to training the driving assistant model using the simulated driving data.

20. The method of claim 1, further comprising:
training a generative rendition model to generate at least one digital image according to at least one physical constraint by providing the generative rendition model with a plurality of training examples, each comprising a plurality of physical constraints of a simulated driving environment and a real digital image corresponding to the plurality of physical constraints, to produce a trained generative rendition model; and
providing the simulated driving data to the driving assistant model for the purpose of one or more of: training the driving assistant model, verifying the driving assistant model, testing the driving assistant model and validating the driving assistant model;
wherein producing the simulated driving data comprises computing at least one synthetic digital image using the trained generative rendition model by providing the trained generative rendition model with another plurality of physical constraints of another simulated driving environment.

21. The method of claim 20, wherein the plurality of physical constraints comprise a plurality of three-dimensional (3D) placements of a plurality of objects in the simulated driving environment.

22. The method of claim 21, wherein the other plurality of physical constraints comprises another plurality of 3D placements of another plurality of objects in the other simulated driving environment.

23. The method of claim 20, wherein the plurality of physical constraints comprises text in at least one natural language.

24. The method of claim 23, wherein the other plurality of physical constraints comprises another text in the at least one natural language.

25. The method of claim 20, wherein the generative rendition model is a previously-trained generative rendition model, trained to generate at least one synthetic digital image in response to data describing an image, the previously-trained generative rendition model trained using a plurality of real digital images.

26. The method of claim 25 wherein the data describing the image is provided in a natural language.

27. The method of claim 20, wherein the generative rendition model is a latent diffusion deep neural network.

28. The method of claim 20, wherein generating the simulated driving data comprises providing the trained generative rendition model with at least one environment-characteristic adjustment value.

29. A system for generating a driving assistant model, comprising at least one hardware processor configured to:
compute at least one semantic driving scenario by computing at least one permutation of at least one initial semantic driving scenario;
provide the at least one semantic driving scenario to a simulation generator to produce simulated driving data describing at least one simulated driving environment;
train a driving assistant model using the simulated driving data to produce a trained driving assistant model; and
execute the trained driving assistant model and at least one autonomous driving model, where the trained driving assistant model provides at least one driving instruction to the at least one autonomous driving model while the at least one autonomous driving model is operating.

30. The system of claim 29, further comprising at least one digital communication network interface connected to the at least one hardware processor;
wherein the trained driving assistant model provides the at least one driving instruction to the at least one autonomous driving model via the at least one digital communication network interface.

31. The system of claim 29, wherein the at least one initial semantic driving scenario is computed using driving event data describing at least one driving event detected in other driving data collected during operation of at least one other autonomous driving model (shadow driver) in a vehicle driven by a human driver;
wherein at least one sensor is installed in the vehicle in an identified configuration;
wherein the at least one autonomous driving model is installed in another vehicle; and
wherein at least one other sensor is installed in the other vehicle in the identified configuration.

32. A software program product for generating a driving assistant model, comprising:
a non-transitory computer readable storage medium;
first program instructions for computing at least one semantic driving scenario by computing at least one permutation of at least one initial semantic driving scenario;
second program instructions for providing the at least one semantic driving scenario to a simulation generator to produce simulated driving data describing at least one simulated driving environment;
third program instructions for training a driving assistant model using the simulated driving data to produce a trained driving assistant model; and
fourth program instructions for execute the trained driving assistant model and at least one autonomous driving model, where the trained driving assistant model provides at least one driving instruction to the at least one autonomous driving model while the at least one autonomous driving model is operating;
wherein the first, second, third and fourth program instructions are executed by at least one computerized processor from the non-transitory computer readable storage medium.
